(19) United States
(12) Patent Application Publication
(10) Pub. No.: US 2025/0285907 A1
(43) Pub. Date: Sep. 11, 2025

(54) METHOD AND APPARATUS FOR PROCESSING SEMICONDUCTOR WAFER

(71) Applicant: TAIWAN SEMICONDUCTOR MANUFACTURING COMPANY LTD., HSINCHU (TW)

(72) Inventors: SUNG-JU HUANG, TAIPEI CITY (TW); YUNG-TSUN LIU, TAIPEI CITY (TW); KUANG-WEI CHENG, HSINCHU CITY (TW)

(21) Appl. No.: 18/597,965

(22) Filed: Mar. 7, 2024

(51) Int. Cl. H01L 21/687

(52) U.S. Cl. CPC H01L 21/68735; H01L 21/68764; H01L 21/68771

(57) ABSTRACT

A semiconductor processing apparatus is provided. The apparatus includes a platen, a carrier ring and a disc. The platen has an opening formed on an upper surface of the platen. The carrier ring is positioned in the opening of the platen. The carrier ring includes a ring body and a protrusion connected to an inner circumference surface of the ring body, the protrusion has a flat engaging surface at its free end. The disc is positioned in the opening of the platen and surrounded by the carrier ring.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

The numerous processing steps are used to cumulatively apply multiple electrically conductive and insulating layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

### BRIEF DESCRIPTION OF THE DRAWINGS

Aspects of the embodiments of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1 is a schematic view illustrating a semiconductor processing apparatus, in accordance with some embodiments of the present disclosure.

FIG. 2 is a top schematic view illustrating the carrier ring holding a semiconductor wafer, in accordance with some embodiments of the present disclosure.

FIG. 3 is an exploded view illustrating a semiconductor wafer, a carrier ring and a disc, in accordance with some embodiments of the present disclosure.

FIG. 4 is a cross-sectional view illustrating the semiconductor processing apparatus taken along line 4-4 of FIG. 2.

FIG. 5A is a schematic diagram showing a temperature distribution of a semiconductor wafer held by a carrier ring without flat engaging surface.

FIG. 5B is a schematic diagram showing a temperature distribution of a semiconductor wafer held by a carrier ring disclosed in some embodiments of the present disclosure.

FIG. 6 is an exploded view illustrating a semiconductor wafer, a carrier ring and a disc, in accordance with some embodiments of the present disclosure.

FIG. 7 is a cross-sectional view illustrating the semiconductor processing apparatus along with a semiconductor wafer, in accordance with some embodiments of the present disclosure.

FIG. 8 is cross-sectional view of illustrating the semiconductor processing apparatus along with a semiconductor wafer, in accordance with some embodiments of the present disclosure.

FIG. 9 is a flow chart illustrating a method for processing a semiconductor wafer having a flat edge, in accordance with various aspects of one or more embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation.

The disclosure relates to semiconductor manufacturing and, more particularly, to semiconductor manufacturing tools and methods for layer deposition on one or more semiconductor wafers.

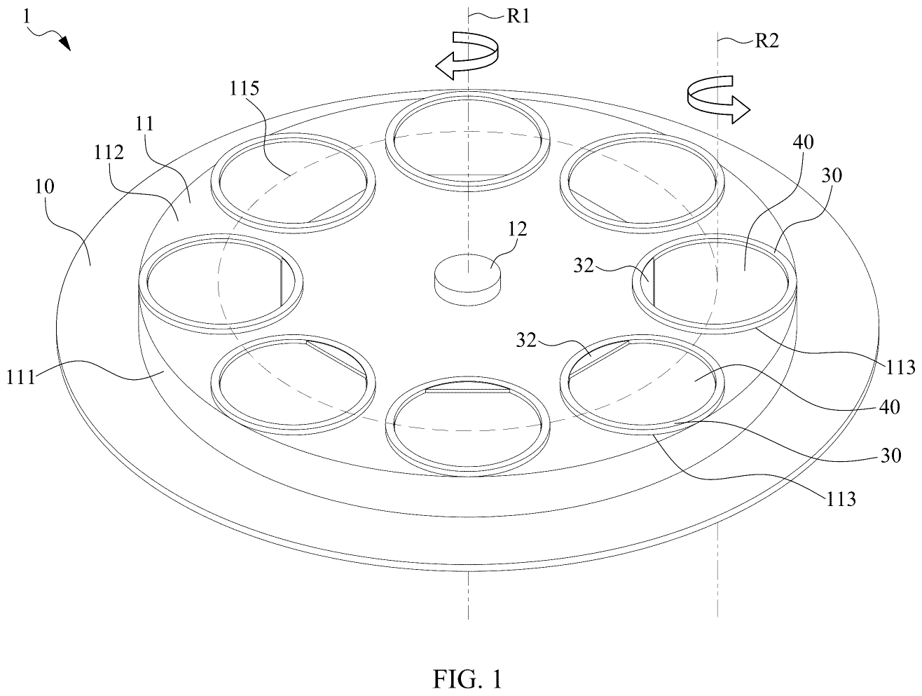

FIG. 1 shows a schematic view illustrating a semiconductor processing apparatus 1, in accordance with some embodiments of the present disclosure. The semiconductor processing apparatus 1 may be semiconductor manufacturing apparatus such as MOCVD (metal organic chemical vapor deposition) tools or other CVD tools or other deposition tools used in the semiconductor manufacturing industry. One or more wafers, i.e. substrates, are disposed on rotatable discs 40 and undergoes processing while the discs 40 is rotating according to various embodiments. Various substrate sizes are used in various embodiments. In one embodiment, as shown in FIG. 1, the carrier rings 30 positioned above the discs 40 are equipped with protrusions 32 and are sized to accommodate substrates. The configurations of the carrier rings 30 allow the substrates to be uniformly heated, resulting in improved thickness uniformity of deposition layers formed on the substrates.

It would be appreciated that although described in conjunction with MOCVD systems, the carrier ring and the disc of the present disclosure find application in all semiconductor and other manufacturing tools that utilize chucks, stages or processing plates with solid upper surfaces for receiving substrates.

In accordance with some embodiments of present disclosure, the semiconductor processing apparatus 1 includes a chamber 10, a platen 11, a gas nozzle 12, a number of carrier rings 30, and a number of discs 40. The elements of the semiconductor processing apparatus 1 can be added to or omitted, and the disclosure should not be limited by the embodiments.

The platen 11, or so-called susceptor, is rotatably around a rotation axis R1 that passing through a center of the platen and is positioned on a bottom wall of the chamber 10. In some embodiments, the platen 11 has a round plate shape with a number of openings 113 (or recesses) formed on an upper surface 112 thereof. The openings 113 are positioned between the rotation axis R1 and the outer circumference 111 of the platen 11 and are arranged along a reference circular line 115 that is concentric with the rotation axis R1. The gas nozzle 12, located at the center of the platen 11, is designed to dispense processing gas horizontally toward the outer circumference 111 of the platen 11. The gas nozzle 12 may be located at a ceiling of the chamber 10 or located on the platen 11. One or more exhaust ports (not shown in figures) may be formed on the bottom wall of the chamber 10 to extracts the processing gas from edges of the chamber 10 after passing over the hot semiconductor substrates (not shown in FIG. 1) and the upper surface 112 of the platen 11. The gas flow radially and very homogeneously from the center to the edge of the chamber 10.

The carrier rings 30 are sized to fit within the associated openings 113 in the platen 11, and the discs 40 are positioned within the openings 113 and positioned below the associated carrier rings 30. The carrier rings 30 circumferentially surround the periphery of the discs 40. The carrier rings 30 are formed of silicon carbide, graphite, graphite coated with silicon carbide and various other suitable materials in various embodiments. The discs 40 are formed of various suitable sturdy and durable materials such as metals, composites graphite and silicon carbide in various embodiments. In one embodiment, the discs 40 are formed of a graphite base with a silicon carbide coating. Various mechanical means can be employed to rotate the carrier rings 30 and the disc 40. For example, a rotation shaft which is coupled to a motor (not shown in figures) is connected to a bottom of the disc 40 so as to drive the rotation of the disc 40. The arrow around rotation axis R2 indicates a counter-clockwise rotation direction of the carrier rings 30 and the disc 40, but in other variations, the carrier rings 30 and the disc 40 can also be rotated clockwise. In some embodiments, the rotation direction of the carrier rings 30 and the discs 40 may be opposite to the rotation direction of the platen 11.

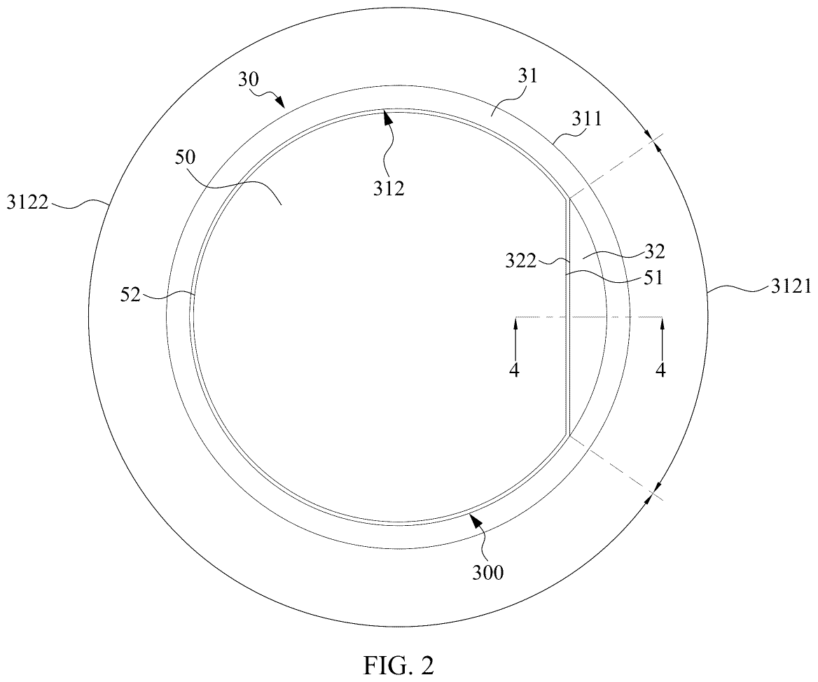

FIG. 2 is a top schematic view illustrating the carrier ring 30 holding a semiconductor wafer 50, in accordance with some embodiments of the present disclosure. In some embodiments, a semiconductor wafer 50 to be processed by the semiconductor processing apparatus is a 6-inch or 8-inch silicon wafer and has a flat edge 51 and a curved edge 52. The flat edge 51 and the curved edge 52 formed an entire peripheral of the semiconductor wafer 50. In some embodiments, the flat edge 51 is cut to indicate the crystallographic planes of the wafer (usually a {110} face) or to convey wafer orientation.

The semiconductor wafer 50 may be made of silicon or other semiconductor materials. Alternatively or additionally, the semiconductor wafer 50 may include other elementary semiconductor materials such as germanium (Ge). In some embodiments, the semiconductor wafer 50 is made of a compound semiconductor such as silicon carbide (SiC), gallium arsenic (GaAs), indium arsenide (InAs), or indium phosphide (InP). In some embodiments, the semiconductor wafer 50 is made of an alloy semiconductor such as silicon germanium (SiGe), silicon germanium carbide (SiGeC), gallium arsenic phosphide (GaAsP), or gallium indium phosphide (GaInP). In some embodiments, the semiconductor wafer 50 includes an epitaxial layer. For example, the semiconductor wafer 50 has an epitaxial layer overlying a bulk semiconductor. In some other embodiments, the semiconductor wafer 50 may be a silicon-on-insulator (SOI) or a germanium-on-insulator (GOI) substrate.

The semiconductor wafer 50 may have various device elements. Examples of device elements that are formed in the semiconductor wafer 50 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, a shallow trench isolation (STI) layer, an inter-layer dielectric (ILD), or an inter-metal dielectric layer covers the device elements formed on the semiconductor wafer 50.

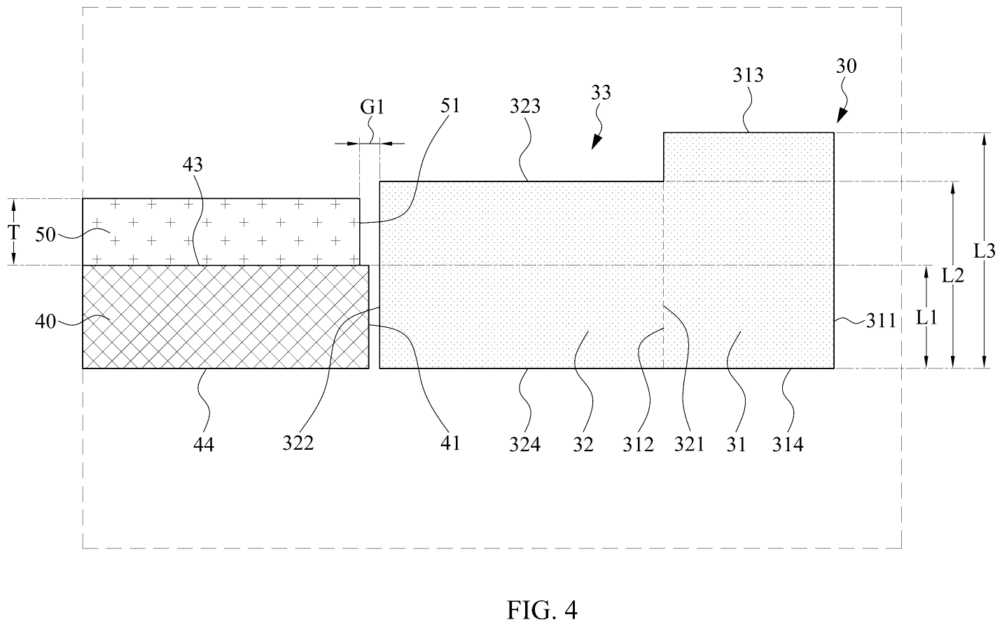

The carrier ring 30 is configured to hold the semiconductor wafer 50. In some embodiments, the carrier ring 30 includes a ring body 31 and a protrusion 32. The ring body 31 is a circular ring with an outer circumference surface 311 and an inner circumference surface 312. The protrusion 32 is a circular segment that is attached to the inner circumference surface 312 of the ring body 31. Specifically, the inner circumference surface 312 consists of two regions (a connecting surface 3121 and a curved engaging surface 3122) positioned around the center of the carrier ring 30. The arced outer surface 321 (FIG. 4) of the protrusion 32 runs along the connecting surface 3121 of the ring body 31, and a flat engaging surface 322, located at a free end of the protrusion 32, connects to both ends of the arced outer surface 321. The protrusion 32 is sized so that a width of the flat engaging surface 322 is slightly greater than a width of the flat edge 51 of the semiconductor wafer 50.

As shown in FIG. 2, the flat engaging surface 322 and the curved engaging surface 3122 together form the engaging surface 300 of the carrier ring 30. In some embodiments, the profile of the engaging surface 300 of the carrier ring 30 is similar to the periphery edge of the semiconductor wafer 50, and the engaging surface 300 of the carrier ring 30 completely surrounds the semiconductor wafer 50. Therefore, when the semiconductor wafer 50 is held by the carrier ring 30, the flat edge 51 of the semiconductor wafer 50 faces the flat engaging surface 322, and the curved edge 52 of the semiconductor wafer 50 faces the curved engaging surface 3122 of the ring body 31.

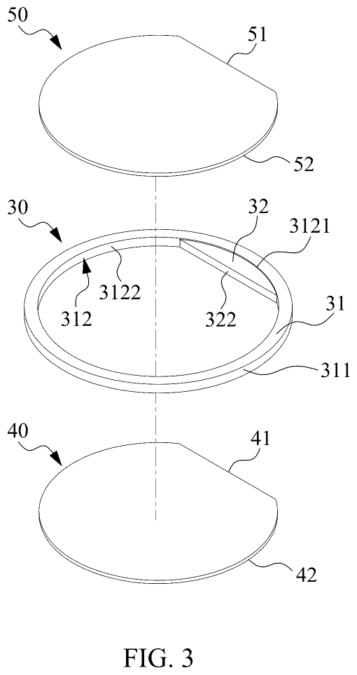

FIG. 3 is an exploded view illustrating the semiconductor wafer 50, the carrier ring 30 and the disc 40, in accordance with some embodiments of the present disclosure. In some embodiments, a peripheral surface of the disc 40 comprises a flat segment 41 and a curved segment 42 extending parallel to the flat engaging surface 322 of the protrusion 32. The disc 40 is surrounded by the carrier ring 30 and positioned below the semiconductor wafer 50. In some embodiments, the carrier ring 30 fits around the disc 40 and the flat segment 41 of the disc 40 is in direct contact with the flat engaging surface 322 of the protrusion 32. The engagement of the flat segment 41 and the flat engaging surface 322 of the protrusion 32 enables the carrier ring 30 and the disc 40 to be rotated at the same rotation speed. Since the disc 40, the carrier ring 30, and the semiconductor wafer 50 are rotate at the same speed, the rotation speed of the semiconductor wafer 50 can be precisely control, the thickness uniformity of the material layer in a layer deposition process can be further improved.

As shown in FIG. 4, in some embodiments, the protrusion 32 extends from a middle region of the inner circumference surface 312 of the ring body 31 to a bottom of the carrier ring 30. That is, a top surface 323 of the protrusion 32 is lower than a top surface 313 of the ring body 31, which results an upper step structure 33 being formed between the top surface 313 of the ring body 31 and the flat engaging surface 322 of the protrusion 32. In addition, a bottom surface 324 of the protrusion 32 flashes with a bottom surface 314 of the ring body 31. A bottom surface of the disc 40 may a placed in a same horizontal plane where the bottom surface 324 of the protrusion 32 and the bottom surface 314 of the ring body 31 locate. However, it will be appreciated that many variations and modifications can be made to embodiments of the disclosure. In some other embodiments, the top surface 323 of the protrusion 32 flashes with the top surface 313 of the ring body 31, and there is no step structure formed on the upper side of the carrier ring 30.

As shown in FIG. 4, a top surface 43 is distant from a bottom surface 44 of the disc 40 by a distance L1 (i.e., a thickness of the disc 40), the top surface 323 is distant from the bottom surface 324 of the protrusion 32 by a distance L2, the top surface 313 is distant from the bottom surface 314 of the ring body 31 by a distance L3, and the semiconductor wafer 50 has a thickness T. In one exemplary embodiment, the distance L3 is equal to or greater than the distance L2, and the distance L2 is equal to or greater than the distance L1. In addition, a height difference between the distance L2 and the distance L1 is equal to or greater than the thickness T of the semiconductor wafer 50. The semiconductor wafer 50 may have a thickness of about 0.8 mm. A sufficient height difference (L2−L1) between the top surface 323 of the protrusion 32 and the top surface 43 of the disc 40 results in that the flat edge 51 of the semiconductor wafer 50 overlaps with the flat engaging surface 322 in a radial direction, allowing for uniform heating by both the carrier ring 30 and the disc 40. In some embodiments, a linear notch is formed between the flat edge 51 of the semiconductor wafer 50 and the flat engaging surface 322 of the carrier ring 30. The linear notch extends parallel to the flat edge 51 of the semiconductor wafer 50 and the flat engaging surface 322 of the carrier ring 30. The linear notch has a uniform width G1 in a direction that is perpendicular to the flat edge 51 of the semiconductor wafer 50 and the flat engaging surface 322 of the carrier ring 30. In one exemplary embodiment, the width G1 is in a range of about 0.6 mm to about 2 mm.

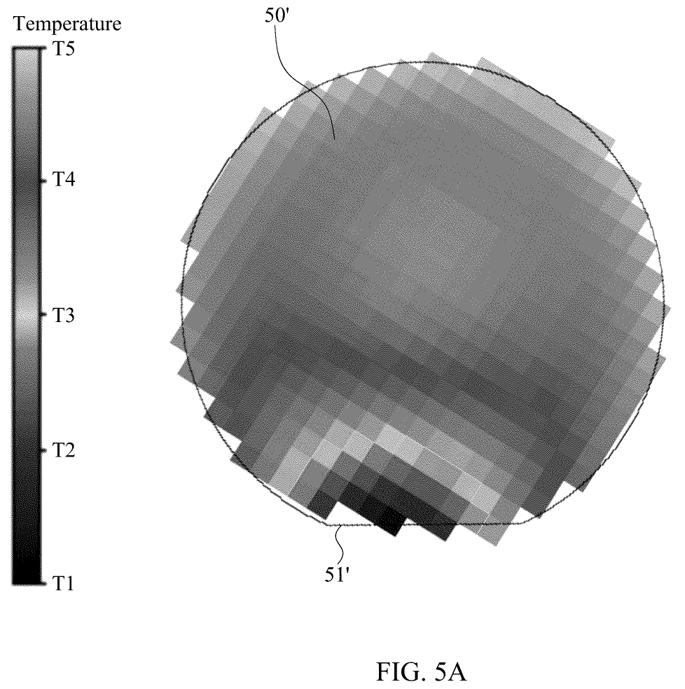

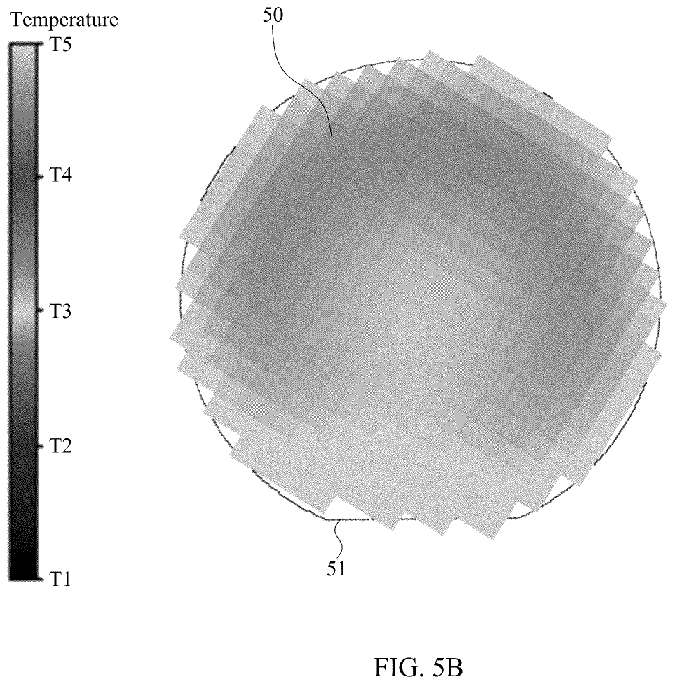

FIG. 5A is a schematic diagram showing a temperature distribution of a semiconductor wafer 50′ held by a conventional carrier ring without flat engaging surface. FIG. 5B is a schematic diagram showing a temperature distribution of a semiconductor wafer 50 held by the carrier ring 30 disclosed in some embodiments of the present disclosure. The carrier ring 30 provides a uniform temperature distribution across the entire surface of the heated semiconductor wafer 50, as depicted in FIG. 5B. In contrast, another type of carrier ring (i.e., a carrier ring without the protrusion) results in lower temperatures near the flat edge 51′ of the semiconductor wafer 50′. Since temperature variation affects the thickness of the material layer formed on the semiconductor wafer (the lower the temperature, the thicker the film thickness), the layer formed on the semiconductor wafer 50 has a higher level of uniformity in thickness as compared to the layer formed on the semiconductor wafer 50′.

In some embodiments, as shown in FIG. 4, a height difference (L3−L2) between the top surface 313 and the top surface 323 creates the upper step structures 33 formed above the protrusions 32. Additionally, as shown in FIG. 1, the protrusions 32 of the carrier ring 30 are positioned closer to the center (through which the rotation axis R1 passes) of the platen 11 than the outer circumference 111 of the platen 11. With these arrangements, the processing gas from the gas nozzle 12 is allowed to flow over the entire surface of the semiconductor wafer 50, including the region adjacent to the flat edge 51. Therefore, the upper step structure 33 leads to a further improvement in the thickness uniformity of the layer formed on the semiconductor wafer 50.

The configuration of the carrier ring 30 and the disc 40 should not be limited to the embodiments above. Some exemplary embodiments of the abrasive brush are described below.

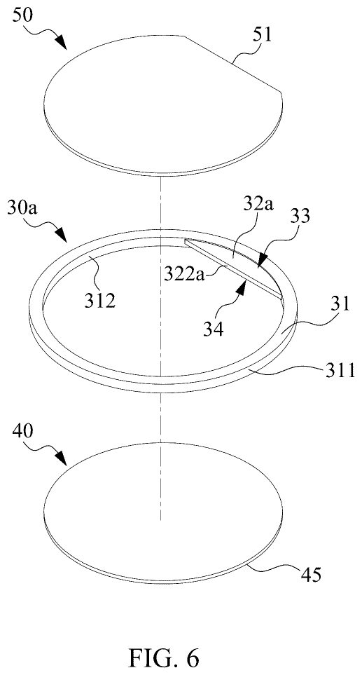

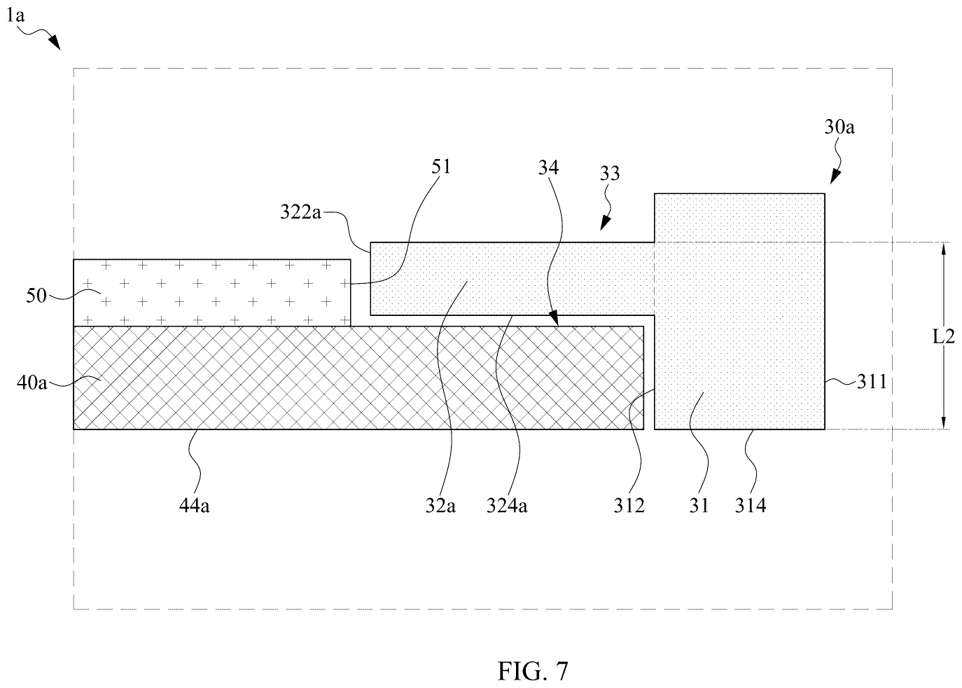

FIG. 6 is an exploded view illustrating the semiconductor wafer 50, a carrier ring 30a and a disc 40a, in accordance with some embodiments of the present disclosure. FIG. 7 is a cross-sectional view illustrating the semiconductor processing apparatus 1a along with a semiconductor wafer 50, in accordance with some embodiments of the present disclosure. The components in FIGS. 6 and 7 that use the same reference numerals as the components of FIGS. 1-4 refer to the same components or equivalent components thereof. For the sake of brevity, it will not be repeated here. Differences between the semiconductor processing apparatus 1 and 1a include the carrier ring 30 and the disc 40 being replaced with a carrier ring 30a and a disc 40a.

As shown in FIG. 7, in some embodiments, in addition to the upper step structure 33 formed on the top side of the carrier ring 30a, the carrier ring 30a further includes a lower step structure 34 formed on the bottom side thereof. That is, the bottom surface 314 of the ring body 31 and a bottom surface 324a of the protrusion 34a are located at different levels. In some embodiments, a height difference between the bottom surface 314 of the ring body 31 and the bottom surface 324a of the protrusion 34a is slightly greater than a thickness of the disc 40a. A bottom surface 44a of the disc 40a flashes with the bottom surface 314 of the ring body 31. As shown in FIG. 6, a peripheral surface of the disc 40a has a circular shape, and a portion of the disc 40a is located below the protrusion 32a. Upon the semiconductor wafer 50 being placed on the disc 40a, the flat edge 51 of the semiconductor wafer 50 overlaps with the flat engaging surface 322a of the protrusion 32a in a radial direction, allowing for uniform heating by both the carrier ring 30a and the disc 40a.

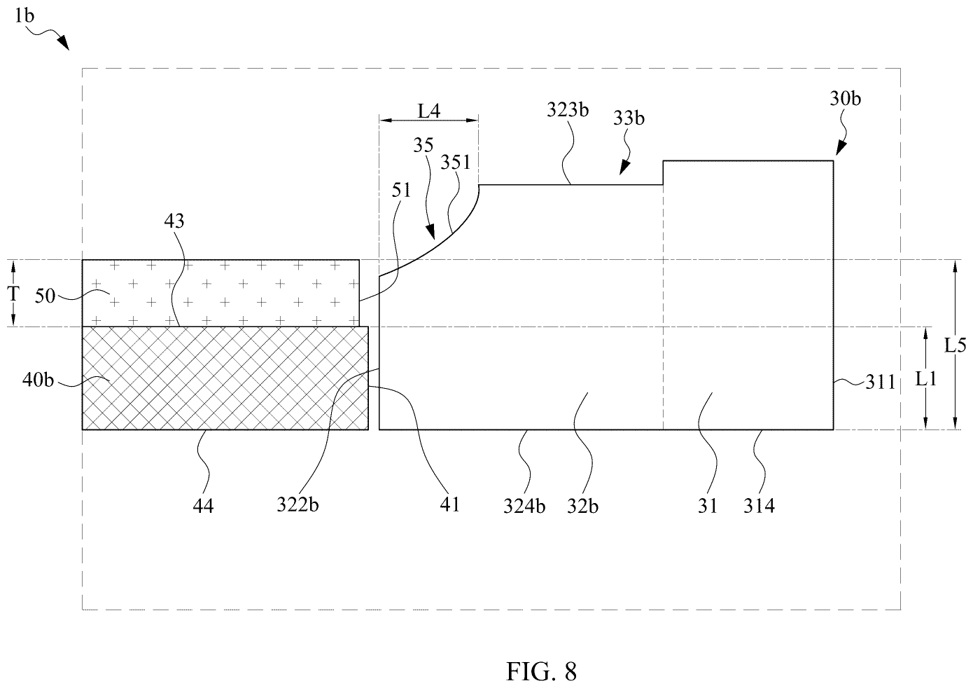

FIG. 8 is cross-sectional view of illustrating the semiconductor processing apparatus 1b along with a semiconductor wafer, in accordance with some embodiments of the present disclosure. The components in FIG. 8 that use the same reference numerals as the components of FIGS. 1-4 refer to the same components or equivalent components thereof. For the sake of brevity, it will not be repeated here. Differences between the semiconductor processing apparatus 1 and 1b include the carrier ring 30 being replaced with a carrier ring 30b.

In accordance with some embodiments, the carrier ring 30b includes the ring body 31 and the protrusion 32b. The protrusion 32b is a circular segment that is attached to the inner circumference surface of the ring body 31. A flat engaging surface 322b is formed at a free end of the protrusion 32b. The protrusion 32b is sized so that a width of the flat engaging surface 322b is slightly greater than a width of the flat edge 51 of the semiconductor wafer 50. A bottom surface 324b of the protrusion 32b flashes with the bottom surface 314 of the ring body 31. When the semiconductor wafer 50 is held by the carrier ring 30b, the flat edge 51 of the semiconductor wafer 50 and the flat segment 41 of the disc 40b face the flat engaging surface 322b in the radial direction.

In some embodiments, a top surface 323b of the protrusion 32b is lower than a top surface of the ring body 31, which results an upper step structure 33b being formed between the top surface of the carrier ring 31 and the flat engaging surface 322b of the protrusion 32b. A guiding slope 35 is formed on a top surface 323b of the protrusion 32b and is immediately adjacent to the flat engaging surface 322b. The guiding slope 35 may include a curved surface 351 connecting the top surface 323b of the protrusion 32b to the flat engaging surface 322b of the protrusion 32b.

In one exemplary embodiment, a width L4 of the curved surface 351, measuring from the bottom to the top of the guiding slope 35 in a radial direction, falls within a range of about 3 mm to about 6 mm. Moreover, a curved profile bottom of the guiding slope 35 is distant from the bottom surface 324b of the protrusion 32b by a distance L5. A height difference (L5−L1) between the curved profile bottom of the guiding slope 35 and the top surface 43 of the disc 40b is in a range of about 0.4 mm to about 0.8 mm, and is less than a thickness T of the semiconductor wafer 50. The guiding slope 35 is used to facilitate the insertion of the semiconductor wafer 50 into the carrier ring 30b or the removal of the semiconductor wafer 50 from the carrier ring 30b.

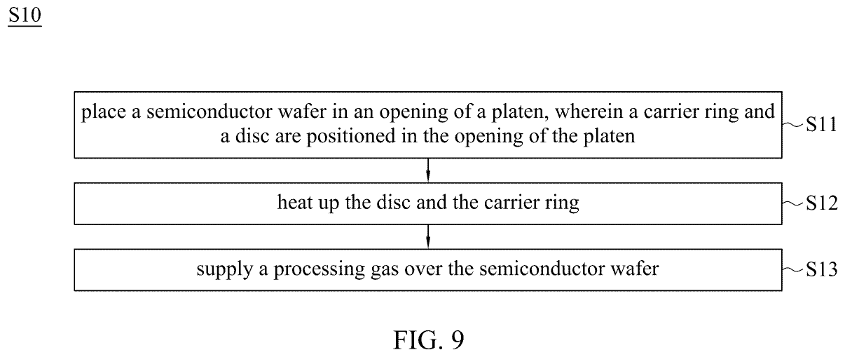

FIG. 9 is a flow chart illustrating a method S10 for processing a semiconductor wafer having a flat edge, in accordance with various aspects of one or more embodiments of the present disclosure. For illustration, the flow chart will be described along with the drawings shown in FIGS. 1-4 and 6-8. Some of the described stages can be replaced or eliminated in different embodiments.

The method S10 includes operation S11, in which a semiconductor wafer 50 is placed into an opening 113 of a platen 11. In some embodiments, a carrier ring 30, 30a, or 30b and a disc 40, 40a or 40b are positioned in the opening 113 of the platen 11. When the semiconductor wafer 50 is placed in the opening 113, the semiconductor wafer 50 is surrounded by the carrier ring 30, 30a, or 30b and supported by the disc 40, 40a or 40b. In addition, the flat engaging surface 322, 322a or 322b and the curved engaging surface 3122 entirely surround the semiconductor wafer 50 with the flat engaging surface 322, 322a or 322b facing the flat edge 51 of the semiconductor wafer 50.

The method S10 also includes operation S12, in which the carrier ring 30, 30a, or 30b and a disc 40, 40a or 40b are heated to control the temperature of the semiconductor wafer 50 at an elevated temperature. A heater, such as multiple electric heating coils (not shown in figures), may be installed in the platen 11. Heat generated from the heaters is transferred to the semiconductor wafer 50 through the platen 11, the carrier ring 30, 30a, or 30b, and a disc 40, 40a or 40b. In the MOCVD process, the wafer is heated at temperatures between 400° C.-1300° C. depending on the material to be deposited.

The method S10 also includes operation S13, in which a processing gas is supplied from the gas nozzle 12. In some embodiments, the process gas provided from the gas nozzle 12 passes over the semiconductor wafer 50 in horizontal direction and is exhausted from the chamber 10 through an exhaust ports of the chamber 10. The gas flow contains precursors, such as trimethylgallium and ammonia (TMGa, NH₃), which decompose when exposed to heat. For example, one gallium (Ga) and one nitrogen atom (N) per precursor molecule are released for the growth of GaN and incorporated into the crystal. The flat edge 51 of the semiconductor wafer 50 overlaps with the flat engaging surface 322 in a radial direction, ensuring a uniform temperature distribution across the entire surface of the semiconductor wafer 50. This results in a material layer with a substantially consistent thickness across the wafer.

Embodiments of the present disclosure provide innovative method for depositing a material layer onto a semiconductor wafer. By utilizing a carrier ring with a flat engaging surface that faces a flat edge of the semiconductor wafer, precise control over the thickness of the material layer can be achieved. This precise control allows for the optimization of the electrical properties of the semiconductor devices, ultimately leading to improved overall functionality and enhanced device performance. Furthermore, this novel technique offers the potential for increased efficiency and cost-effectiveness in the manufacturing process. By ensuring a uniform and consistent material layer thickness, the need for rework and adjustments is minimized, leading to reduced production time and costs. Additionally, the improved electrical properties of the semiconductor devices can lead to enhanced reliability, further adding value to the end products.

According to some embodiments of present disclosure, a semiconductor processing apparatus is provided. The apparatus includes a platen, a carrier ring and a disc. The platen has an opening formed on an upper surface of the platen. The carrier ring is positioned in the opening of the platen. The carrier ring includes a ring body and a protrusion connected to an inner circumference surface of the ring body, the protrusion has a flat engaging surface at its free end. The disc is positioned in the opening of the platen and surrounded by the carrier ring.

According to some alternative embodiments of present disclosure, the apparatus includes a platen, a carrier ring and a disc. The platen has an opening formed on an upper surface of the platen. The carrier ring is positioned in the opening of the platen. The carrier ring includes an engaging surface configured to entirely surround a semiconductor wafer, and the engaging surface comprises a flat engaging surface and a curved engaging surface. The disc is positioned in the opening of the platen and surrounded by the carrier ring.

According to other embodiments of present disclosure, a method for processing a semiconductor wafer having a flat edge is provided. The method includes placing the semiconductor wafer in an opening of a platen. A carrier ring and a disc are positioned in the opening of the platen, when the semiconductor wafer is placed in the opening, the semiconductor wafer is surrounded by the carrier ring and supported by the disc. The carrier ring includes a flat engaging surface and a curved engaging surface, the flat engaging surface and the curved engaging surface entirely surround the semiconductor wafer with the flat engaging surface facing the flat edge of the semiconductor wafer. The method further includes heating up the disc and the carrier ring. The method also includes supplying a processing gas over the semiconductor wafer.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor processing apparatus, comprising:
a platen, having an opening formed on an upper surface of the platen;
a carrier ring, positioned in the opening of the platen, wherein the carrier ring comprises a ring body and a protrusion connected to an inner circumference surface of the ring body, the protrusion has a flat engaging surface at its free end; and
a disc, positioned in the opening of the platen and surrounded by the carrier ring.

2. The semiconductor processing apparatus of claim 1, wherein the protrusion has an arced outer surface extends along the inner circumference surface of the ring body, the flat engaging surface is connected between two ends of the arced outer surface.

3. The semiconductor processing apparatus of claim 1, wherein a top surface of the ring body and a top surface of the protrusion are located at different levels.

4. The semiconductor processing apparatus of claim 3, wherein a height difference between the top surface of the protrusion and a top surface of the disc is greater than a thickness of a semiconductor wafer to be processed by the semiconductor processing apparatus.

5. The semiconductor processing apparatus of claim 3, wherein a bottom surface of the ring body and a bottom surface of the protrusion are located at the same level, and a peripheral surface of the disc comprises a curved segment and a flat segment extending parallel to the flat engaging surface of the protrusion.

6. The semiconductor processing apparatus of claim 3, wherein a bottom surface of the ring body and a bottom surface of the protrusion are located at different levels, and a peripheral surface of the disc has a circular shape, a portion of the disc is located below the protrusion.

7. The semiconductor processing apparatus of claim 1, wherein a guiding slope is formed on a top surface of the protrusion and is immediately adjacent to the flat engaging surface.

8. The semiconductor processing apparatus of claim 1, wherein the opening is located between a center of the platen and an outer circumference of the platen, and the protrusion of the carrier ring is closer to the center of the platen than the outer circumference of the platen.

9. A semiconductor processing apparatus, comprising:
a platen, having an opening formed on an upper surface of the platen;
a carrier ring, positioned in the opening of the platen, wherein the carrier ring comprises an engaging surface configured to entirely surround a semiconductor wafer, and the engaging surface comprises a flat engaging surface and a curved engaging surface; and
a disc, positioned in the opening of the platen and surrounded by the carrier ring.

10. The semiconductor processing apparatus of claim 9, wherein an upper step structure is formed between a top surface of the carrier ring and the flat engaging surface.

11. The semiconductor processing apparatus of claim 10, wherein a distance between a top surface of the disc and an intermediate edge, which is formed between the upper step structure and the flat engaging surface, is greater than a thickness of the semiconductor wafer.

12. The semiconductor processing apparatus of claim 10, wherein the carrier ring comprises a lower surface which extends flat from an outer circumference surface of the carrier ring to the flat engaging surface, and wherein a peripheral surface of the disc comprises a curved segment and a flat segment extending parallel to the flat engaging surface.

13. The semiconductor processing apparatus of claim 10, wherein a lower step structure is formed between a lower surface of the carrier ring and the flat engaging surface, and
wherein a peripheral surface of the disc has a circular shape, and a portion of the disc is positioned within the lower step structure.

14. The semiconductor processing apparatus of claim 10, wherein a guiding slope is formed on the upper step structure and is immediately adjacent to the flat engaging surface.

15. The semiconductor processing apparatus of claim 9, wherein the carrier ring comprises a ring body and a protrusion connected to an inner circumference surface of the ring body, wherein the flat engaging surface is formed at a free end of the protrusion, and the curved engaging surface is a segment of the inner circumference surface of the ring body.

16. The semiconductor processing apparatus of claim 9, wherein the opening is located between a center of the platen and an outer circumference of the platen, and the flat engaging surface of the carrier ring is closer to the center of the platen than the outer circumference of the platen.

17. A method for processing a semiconductor wafer having a flat edge, the method comprising:
placing the semiconductor wafer in an opening of a platen, wherein a carrier ring and a disc are positioned in the opening of the platen, when the semiconductor wafer is placed in the opening, the semiconductor wafer is surrounded by the carrier ring and supported by the disc,
heating up the disc and the carrier ring; and
supplying a processing gas over the semiconductor wafer,
wherein the carrier ring comprises a flat engaging surface and a curved engaging surface, the flat engaging surface and the curved engaging surface entirely surround the semiconductor wafer with the flat engaging surface facing a flat edge of the semiconductor wafer.

18. The method as claimed in claim 17, further comprising rotating the carrier ring, wherein during the rotation of the carrier ring, the flat engaging surface abuts against the flat edge of the semiconductor wafer so as to rotate the semiconductor wafer together.

19. The method as claimed in claim 17, wherein the processing gas is supplied through a nozzle located above a center of the platen, and the opening of the platen is located between the center of the platen and an outer circumference of the platen, and the flat engaging surface of the carrier ring is closer to the center of the platen than the outer circumference of the platen.

20. The method as claimed in claim 17, wherein placing the semiconductor wafer into the opening further comprises moving an edge of the semiconductor wafer along a guiding slope formed on the carrier ring.
